(19) United States
(12) Patent Application Publication
(10) Pub. No.: US 2017/0250364 A1
(43) Pub. Date: Aug. 31, 2017

(54) ORGANIC LIGHT-EMITTING DIODE (OLED) DISPLAY PANEL AND DISPLAY APPARATUS

(71) Applicants: Shanghai Tianma AM-OLED Co., Ltd., Shanghai (CN); Tianma Micro-Electronics Co., Ltd., Shenzhen (CN)

(72) Inventors: Zhihong LEI, Shanghai (CN); Yuji HAMADA, Shanghai (CN); Jinghua NIU, Shanghai (CN); Chen LIU, Shanghai (CN); Xiangcheng WANG, Shanghai (CN); Wei HE, Shanghai (CN)

(21) Appl. No.: 15/592,407

(22) Filed: May 11, 2017

(30) Foreign Application Priority Data
Dec. 14, 2016 (CN) 201611155175.5

(51) Int. Cl. H01L 51/50; H01L 27/32; H01L 51/52

(52) U.S. Cl. CPC H01L 51/5036; H01L 51/5218; H01L 51/5206; H01L 51/5231; H01L 27/322; H01L 51/5076; H01L 2251/5315; H01L 2251/301; H01L 2251/5307; H01L 2251/308; H01L 2251/558; H01L 51/5016; H01L 51/5012; H01L 2251/5376

(57) ABSTRACT

An organic light-emitting diode (OLED) display panel and an OLED display apparatus are provided. The OLED display panel comprises: a substrate; a first electrode and a second electrode disposed in a stacked configuration and on a same side of the substrate; an organic luminescent layer disposed between the first electrode and the second electrode; and an electron transport layer, disposed between the organic luminescent layer and the second electrode and including a predetermined volume percentage of element ytterbium (Yb).

### CROSS-REFERENCES TO RELATED APPLICATIONS

This application claims priority of Chinese Patent Application No. 201611155175.5, filed on Dec. 14, 2016, the entire contents of which are hereby incorporated by reference.

### FIELD OF THE INVENTION

The present disclosure generally relates to the field of organic light-emitting diode (OLED) display technology and, in particular, relates to an OLED display panel and a display apparatus thereof.

### BACKGROUND

OLED displays have become one of the most important trends in the display industry, because of their various technological advantages, such as working without a backlight source, high contrast ratio, thin thickness, wide viewing angle and fast response. An existing OLED display panel comprises a cathode, an electron transport layer, a light-emitting layer, a hole transport layer, an anode and a substrate. In operation, a bias voltage is applied between the cathode and the anode. As a result, holes and electrons pass through the interface barrier, and respectively migrate from the hole transport layer and the electron transport layer towards the light-emitting layer where electrons and holes further recombine to form excitons.

The formed excitons are substantially unstable, which release and transfer the energy to organic luminescent molecules in the light-emitting layer. The transferred energy leads to the energetical transition in the organic luminescent molecules from the ground state to the excited state. The light emission is consequently generated from the luminescent molecules by the spontaneous radiation decay from the excited state back to the ground state.

In the existing OLED display panel, the interface barrier between the organic material and the electrode often determines the number of injected carriers, panel brightness and efficiency. However, the interface barrier between the electron transport layer and the cathode may be substantially high in the existing OLED display panels, resulting in the limited capability of electron injection and, accordingly, the poor performance of OLED display panel.

The disclosed OLED display panel and OLED display apparatus thereof are directed to solve one or more problems set forth above and other problems.

### BRIEF SUMMARY OF THE DISCLOSURE

One aspect of the present disclosure provides an OLED display panel. The OLED display panel comprises: a substrate; a first electrode and a second electrode disposed in a slacked configuration and on a same side of the substrate; an organic luminescent layer disposed between the first electrode and the second electrode; and an electron transport layer, disposed between the organic luminescent layer and the second electrode and including a predetermined volume percent age of element ytterbium (Yb).

Other aspects of the present disclosure can he understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic diagram of an exemplary OLED display panel consistent with disclosed embodiments;

FIGS. 2a-2d illustrate a performance comparison between an existing OLED display panel and an exemplary OLED display panel consistent with disclosed embodiments;

FIGS. 3a-3e illustrate a performance comparison of five exemplary OLED display panels consistent with disclosed embodiments;

FIG. 4 illustrates a schematic diagram of another exemplary OLED display panel consistent with disclosed embodiments;

FIG. 5 illustrates a schematic diagram of another exemplary OLED display panel consistent with disclosed embodiments;

FIG. 6 illustrates a schematic diagram of another exemplary OLED display panel consistent with disclosed embodiments;

FIG. 7 illustrates a schematic diagram of another exemplary OLED display panel consistent with disclosed embodiments;

FIG. 8 illustrates a comparison of light transmittance between an existing OLED display panel and an exemplary OLED display panel consistent with disclosed embodiments;

FIG. 9 illustrates a schematic diagram of another exemplary OLED display panel consistent with disclosed embodiments;

FIG. 10 illustrates a schematic diagram of another exemplary OLED display panel consistent with disclosed embodiments; and

FIG. 11 illustrates a schematic diagram of an exemplary OLED display apparatus consistent with disclosed embodiments.

### DETAILED DESCRIPTION

Reference will now be made in detail to exemplary embodiments of the invention, which are illustrated in the accompanying drawings. Hereinafter, embodiments consistent with the disclosure will be described with reference to drawings. Wherever possible, the same reference numbers will be used throughout the drawings to refer to the same or like parts. It is apparent that the described embodiments are some but not all of the embodiments of the present invention. Based on the disclosed embodiments, persons of ordinary skill in the art may derive other embodiments consistent with the present disclosure, all of which are within the scope of the present invention. Further, in the present disclosure, the disclosed embodiments and the features of the disclosed embodiments may be combined under conditions without conflicts.

The present disclosure provides an improved OLED display panel capable of reducing the interface barrier between the electron transport layer and the cathode and, thus, improving the display performance.

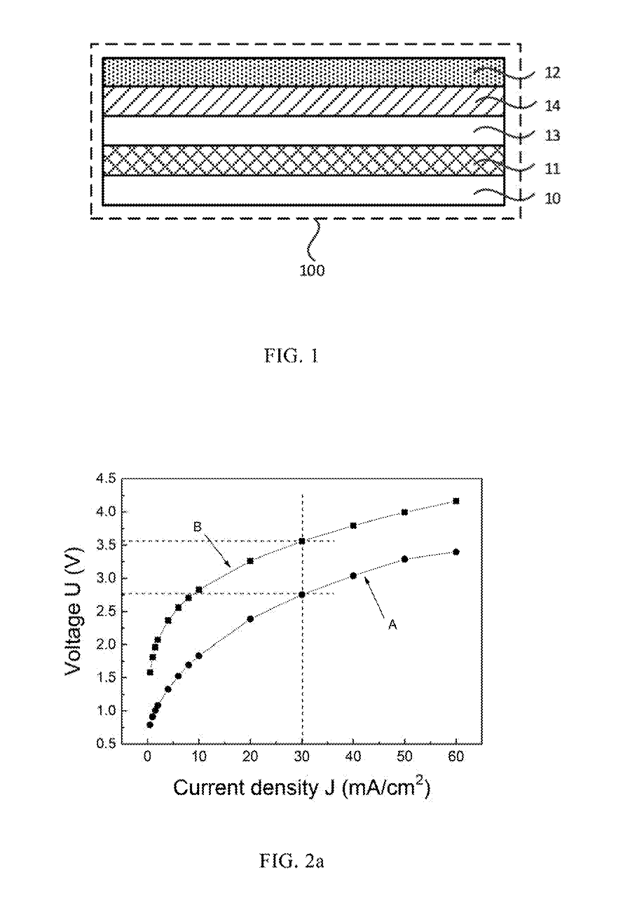

FIG. 1 illustrates a schematic structure diagram of an exemplary OLED display panel consistent with disclosed embodiments. As shown in FIG. 1, the OLED display panel 100 may comprise a plurality of thin films disposed in a stacked configuration; a substrate 10, a first electrode 11, a second electrode 12, an organic luminescent layer 13, and an electron transport layer 14. Other appropriate components may also be included.

In particular, the first electrode 11 and the second electrode 12 may be both disposed on the same side of the substrate 10. The organic luminescent layer 13 may be disposed between the first electrode 11 and the second electrode 12. The electron transport layer 14 may be disposed between the organic luminescent layer 13 and the second electrode 12.

The electron transport layer 14 may include active metals, such as alkali metals, alkaline earth metals, or rare-earth metals, or active metals doped with organic materials. The active metals may he sandwiched between the electron transport layer 14 and the cathode. In one embodiment the electron transport layer 14 may contain an element of ytterbium (Yb), which is one of the rare-earth metals with atomic number 70 in the lanthanide series of the periodic tables. The volume percentage of element Yb may be equal to or less than approximately 3%. The first electrode 11 and the second electrode 12 may be an anode and a cathode, respectively.

According to the Fowler-Nordheim tunneling model, the element Yb in the electron transport layer 14 may reduce the interfacial energy barrier (i.e., interface barrier) between the second electrode 12 and the electron transport layer 14. In the existing OLED display panels, the electron transport layer 14 may not contain the element Yb.

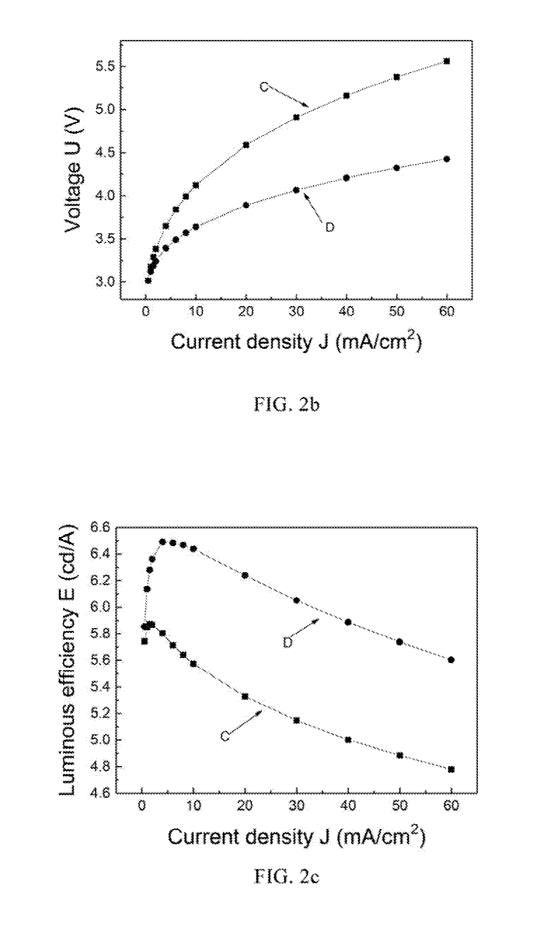

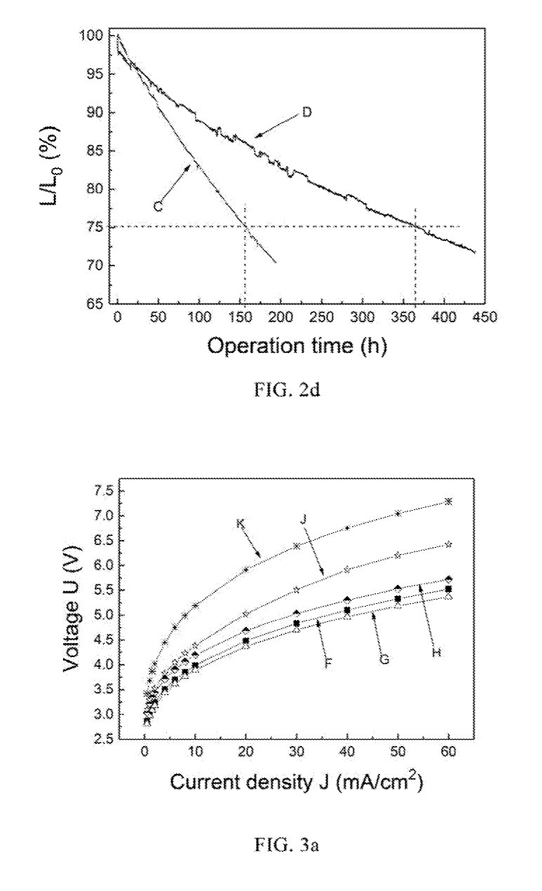

FIG. 2a illustrates a performance comparison between an existing OLED device B and an exemplary OLED device A consistent with disclosed embodiments. The OLED device A contains the element Yb in the electron transport layer 14, while the OLED device B does not contain the element Yb in the electron transport layer 14.

As shown in FIG. 2a, the abscissa represents the current density, J, in the device in a unit of milliamps per square centimeter (mA/cm²), and the ordinate represents the bias voltage U, applied to the device in a unit of volts (V). Given the same current density J, the bias voltage applied to the disclosed OLED device A may be much lower than the bias voltage applied to the existing OLED device B, indicating that the element Yb introduced into the electron transport layer 14 may reduce the interface barrier and, thus, enhance the electron injection capability.

FIGS. 2b-2d illustrate a performance comparison between an existing display panel and an exemplary OLED display panel consistent with disclosed embodiments. As shown in FIGS. 2b-2d, the display panel C represents an existing OLED display panel without the element Yb in the electron transport layer 14, and the display panel D represents a disclosed OLED display panel with the element Yb in the electron transport layer 14.

As shown in FIG. 2b, the abscissa represents the current density, J, of the OLED display panel in milliamps per square centimeter (mA/cm²), and the ordinate represents the bias voltage, U, applied to the OLED display panel in volts (V). Given the same current density J, the bias voltage U applied to the disclosed OLED display panel D may be much lower than the bias voltage applied to the existing OLED display panel C, indicating that the element Yb introduced into the electron transport layer 14 may reduce the interface barrier between the second electrode 12 (i.e., the cathode) and the electron transport layer 14. Accordingly, the electron injection from the second electrode 12 may be facilitated, the earner balance in the OLED display panel may be improved, and the operating voltage (i.e., the bias voltage) of the OLED display panel may be reduced.

As shown in FIG. 2c, the abscissa represents the current density, J, of the OLED display panel in in milliamps per square centimeter (mA/cm²), and the ordinate represents the Luminous efficiency, E, of the OLED display panel in candela per ampere (cd/A). Given the same current density J, the luminous efficiency E of the disclosed OLED display panel D may be much higher than the luminous efficiency E of the existing OLED display panel C, indicating that the element Yb introduced info the election transport layer 14 may increase the luminous efficiency of the OLED display panel and, accordingly, improve the performance of the OLED display panel.

As shown in FIG. 2d, the abscissa represents the operation lime of the OLED display panel in a unit of hour (h), and the ordinate represents the ratio of the OLED display panel's luminance (L) to the OLED display panel's initial luminance (L₀). The luminance of OLED display panels often decays as the operation time increases. For the disclosed OLED display panel D, after approximately 370 operation hours, the luminance may decay to approximately 75% of the initial luminance. For the existing OLED display panel C, after approximately 160 operation hours, the luminance may decay to approximately 75% of the initial luminance.

That is, the operation time of the disclosed OLED display panel D may be much longer than the operation time of the existing OLED display panel C, indicating that the disclosed OLED display panel D may have a longer lifetime than the existing OLED display panel C. In other words, the element Yb introduced into the electron transport layer 14 may prolong the lifetime of the OLED display panel.

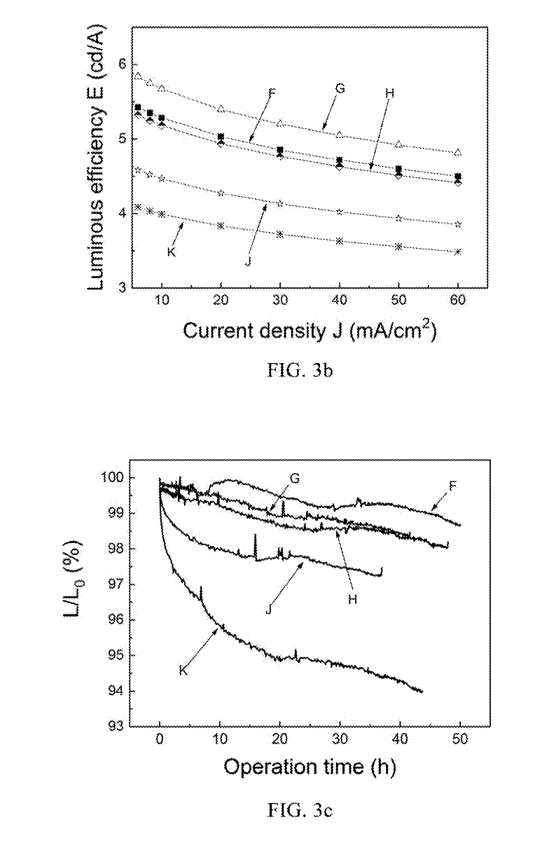

FIGS. 3a-3c illustrate a performance comparison of five exemplary OLED display panels consistent with disclosed embodiments, in which each OLED display panel may be provided with a different volume percentage of element Yb in the electron transport layer 14.

As shown in FIGS. 3a-3c, the display panel F represents an OLED display panel provided with a 1% volume of element Yb in the electron transport layer 14, the display panel G re presents an OLED display panel provided with a 3% volume of element Yb in the electron transport layer 14, the display panel H represents an OLED display panel provided with a volume of element Yb in the electron transport layer 14, the display panel J represents an OLED display panel provided with a 7% volume of element Yb in the electron transport layer 14, and the display panel K represents an OLED display panel provided with a 9% volume of element Yb in the electron transport layer 14.

As shown in FIG. 3a, the abscissa represents the current density, J, of OLED display panel in milliamps per square centimeter (mA/cm²), and the ordinate represents the bias voltage, U, applied to the OLED display panel in volts (V). Referring to FIG. 3a, given the same current density J, the OLED display panels are arranged in the ascending order of the applied bias voltages U as follows: G<F<H<J<K.

As shown in FIG. 3b, the abscissa represents the current density, J, of OLED display panel in milliamps per square centimeter (mA/cm²), and the ordinate represents the luminous efficiency, E, of OLED display panel in candela per ampere (cd/A). Referring to FIG. 3b, given the same current density J, the OLED display panels are arranged in the ascending order of the luminous efficiency E as follows: K<J<H<F<G.

As shown in FIG. 3c, the abscissa represents the operation time of OLED display panel in a unit of hour (h), and the ordinate represents the ratio of the OLED display panel's luminance (L) to the OLED display panel's initial luminance (L₀). Referring to FIG. 3c, given the same ratio of L to L₀, the OLED display panels G, F and H may have significantly longer operation time than the other OLED display panels, J and K.

In summary, the OLED display panels provided with different volume percentages of element Yb in the electron transport layer 14 may differ in the performance, in practical applications, the volume percentage of element Yb may be adjusted based on the various performance requirements of the OLED display panel. In one embodiment, the volume percentage of the element Yb maybe configured to be equal to or less than 3% (i.e., ≦3%).

According to FIGS. 3a-3e, when the volume percentage of the element Yb is configured to be ≦3%, the Schottky barrier may be effectively reduced, and the electron injection capability maybe improved. Thus, the carrier balance in the OLED display panel may be improved, and the performance of the OLED display panels may be enhanced, accordingly.

Further, in one embodiment, as shown in FIG. 1, the first electrode 11 may be disposed between the second electrode 12 and the substrate 10. In practical applications, the OLED display panel may be fabricated as a top-emission, a bottom-emission, or a double-side emission display panel according to various application scenarios.

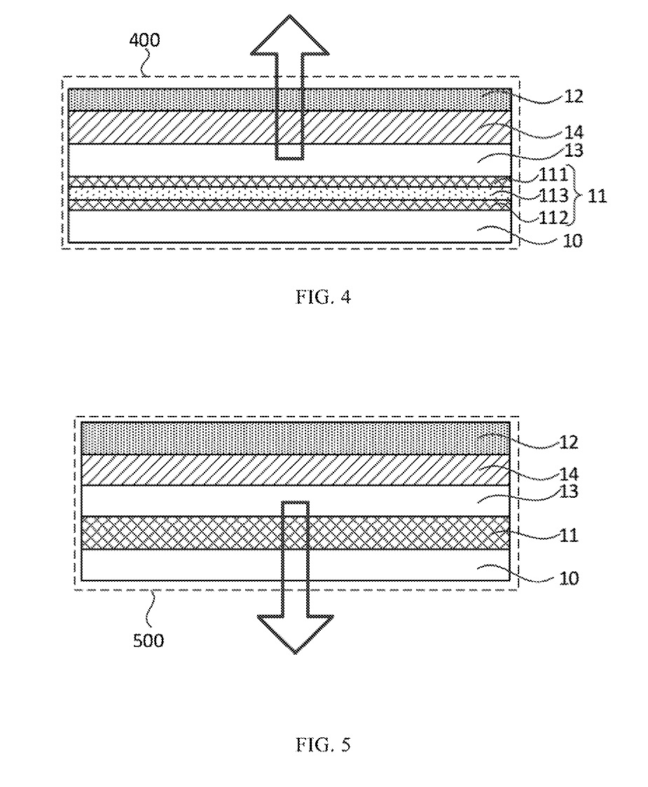

FIG. 4 illustrates a schematic diagram of another exemplary OLED display panel consistent with disclosed embodiments. The similarities between FIG. 1 and FIG. 4 are not repeated here, while certain differences may be explained.

As shown in FIG. 4, the OLED display panel 400 may be a top-emission OLED display panel. The second electrode 12 disposed on the top of the panel maybe the light-output-side electrode. That is, the light generated in the organic luminescent layer 13 may be emitted from the top electrode (i.e., the second electrode 11) after passing through the electron transport layer 14. In particular, the first electrode may include a first transparent conductive film 111, a second transparent conductive film 112, and a reflective film 113 sandwiched between the first transparent conductive film 111 and the second transparent conductive film 112. The second electrode 12 may include metals or metal alloys, such as silver or a silver-based alloy.

The respective layers of the first electrode 11 may have various materials and thicknesses according to various application scenarios, provided that the first electrode 11 has a desired hole injection capability and a desired light reflectivity. For example, in one embodiment, both the first transparent conductive film 111 and the second transparent conductive film 112 in the first electrode 11 may be composed of indium tin oxide or indium zinc oxide, and the reflective film 113 may be composed of silver or silver-based alloy. The thickness of the reflective film 113 may range from approximately 50 nm to 150 nm.

Similarly, the thickness of the second electrode 12 may also vary according to various application scenarios, provide that the second electrode 12 has a desired electron injection capability and a desired light transmittance. For example, in one embodiment, the second electrode 12 may be composed of silver-based alloy, the volume percentage of silver may be equal to or larger than approximately 80%, and the thickness of the second electrode 12 may range from approximately 10 nm to 20 nm.

FIG. 5 illustrates a schematic diagram of another exemplary OLED display panel consistent with disclosed embodiments. The similarities between FIG. 1 and FIG. 5 are not repealed here, while certain differences may be explained.

As shown in FIG. 5, the OLED display panel 500 may he a bottom-emission OLED display panel. The first electrode 11 disposed at the bottom of the panel may be the light-output-side electrode. That is, the light generated in the organic luminescent layer 13 may be emitted from the bottom electrode (i.e., the first electrode 11) and the substrate 10. The first electrode 11 may comprise transparent conductive materials, and the materials of the second electrode 12 may include metals or metal alloys, such as silver or a silver-based alloy.

The materials and thicknesses of the first electrode 11 may vary according to various application scenarios, provided that the first electrode has a desired hole injection capability and a desired light transmittance. For example, in one embodiment, the first electrode 11 may be composed of indium tin oxide or indium zinc oxide.

Similarly, the materials and thicknesses of the second electrode 12 may also vary according to various application scenarios, provided that the second electrode 12 has a desired electron injection capability and a desired reflectivity. For example, in one embodiment, the second electrode 12 may he composed of a silver-based, alloy, in which the volume percentage of silver is equal to or larger than approximately 80%, and the thickness of the second electrode may vary between approximately 50 nm and 150 nm.

FIG. 6 illustrates a schematic diagram of another exemplary OLED display panel consistent with disclosed embodiments. The similarities between FIG. 1 and FIG. 6 are not repeated here, while certain differences may be explained.

As shown in FIG. 6, in the OLED display panel 600, the second electrode 12 may be disposed between the first electrode 11 and the substrate 10. Impractical applications, the OLED display panel may also be fabricated as a top-emission, a bottom-emission, or a double-side emission display panel according to various application scenarios.

In one embodiment, as shown in FIG. 6, the disclosed OLED display panel 600 may be a top-emission OLED display panel. The first electrode 11 disposed on the top of the panel may be the light-output-side electrode. That is, the light generated in the organic luminescent layer 13 may be emitted from the first electrode 11. The first electrode 11 may comprise transparent conductive materials, and the materials of the second electrode 12 may include metals or metal alloys, such as silver or a silver-based alloy.

The materials and thicknesses of the first electrode 11 may vary according to various application scenarios, provided that the first electrode has a desired hole injection capability and a desired light transmittance. For example, in one embodiment, the first electrode 11 may be composed of indium tin oxide or indium zinc oxide.

Similarly, the materials and thicknesses of the second electrode 12 may also vary according to various application scenarios, provided that the second electrode 12 has a desired electron injection capability and a desired reflectivity. For example, in one embodiment, the second electrode 12 may be composed of a silver-based alloy, in which the volume percentage of silver may be equal to or larger than approximately 80%, and the thickness of the second electrode may vary between approximately 50 nm and 150 nm.

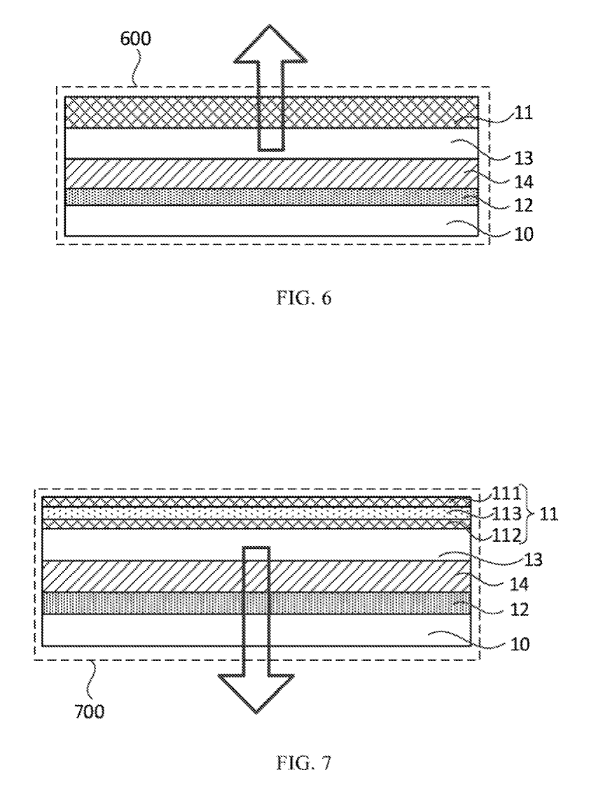

FIG. 7 illustrates a schematic diagram of another exemplary OLED display panel consistent with disclosed embodiments. The similarities between FIG. 6 and FIG. 7 are not repeated here, while certain differences may be explained.

As shown in FIG. 7, the OLED display panel 700 may be a bottom-emission OLED display panel. The second electrode 12 disposed at the bottom of the panel may be the light-output-side, that is, the light generated in the organic luminescent layer 13 may be emitted from the bottom electrode (i.e., the second electrode 12) and the substrate 10 after passing through the electron transport layer 14.

In particular, the first electrode may include a first transparent conductive film 111, a second transparent conductive film 112, and a reflective film 113 sandwiched between the first transparent conductive film 111 and the second transparent conductive film 112. The second electrode 12 may include metals or metal alloys, such as silver or a silver-based alloy.

The respective layers of the first electrode 11 may have various materials and thicknesses according to various application scenarios, provided that the first electrode 11 has a desired hole injection capability and a desired light reflectivity. For example, in one embodiment, both the first transparent conductive film 111 and the second transparent conductive film 112 in the first electrode 11 may be composed of indium tin oxide or indium zinc oxide, and the reflective film 113 may be composed of silver or silver-based alloy. The thickness of the reflective film 113 may range from approximately 50 nm to 150 nm.

Similarly, the thickness of the second electrode 12 may also vary according to various application scenarios, provide that the second electrode 12 has a desired electron injection capability and a desired light transmittance. For example, in one embodiment, the second electrode 12 may be composed of silver-based alloy, in which the volume percentage of silver may be equal to or larger than approximately 80%. The thickness of the second electrode 12 may range from approximately 10 nm to 20 nm.

In one embodiment, the OLED display panel may be a double-side emission OLED display panel in which both the first electrode 11 and the second electrode 12, disposed at the two sides of the panel, may be the light-output-side electrode. That is, the light generated in the organic luminescent layer 13 may be emitted from the top after passing through the first electrode 11 and, meanwhile, may be emitted from the bottom after sequentially passing through the electron transport layer 14, the second electrode 12 and the substrate 10.

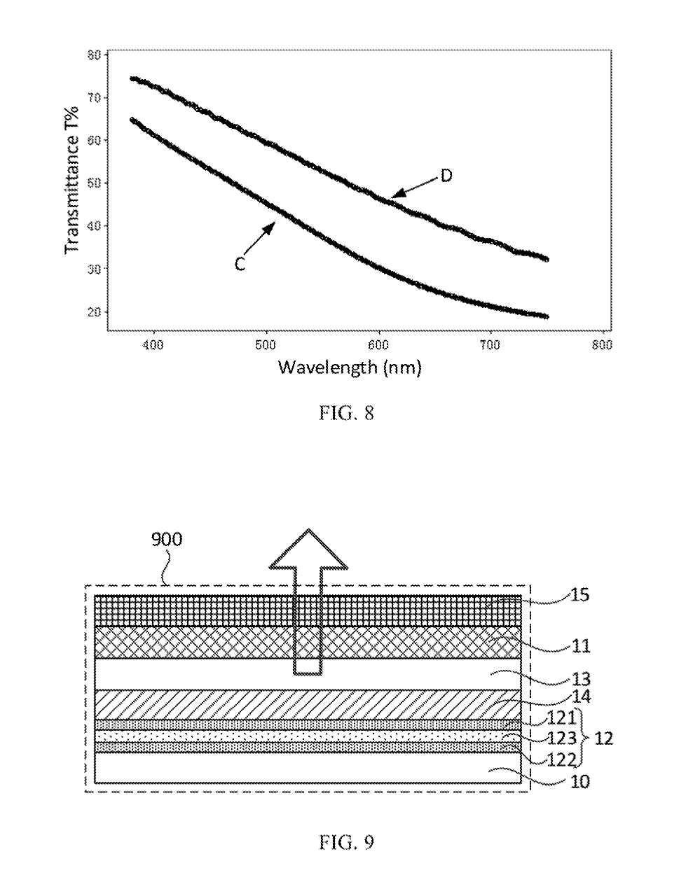

FIG. 8 illustrates a comparison of light transmittance between an existing OLED display panel and an exemplary OLED display panel consistent with disclosed embodiments. The light transmittance is measured at the side of the OLED display panel, where the second electrode 12 is disposed and the light generated in the organic luminescent layer 13 is emitted alter sequentially passing through the electron transport layer 14 and the second electrode 12 (i.e., the cathode).

As shown in FIG. 8, the abscissa represents wavelength of the light emitted from the OLED display panel in a unit of nanometer (nm), the ordinate represents the light transmittance, T %, the display panel C represents an existing OLED display panel without the element Yb in the electron transport layer 14, and the display panel D represents an exemplary OLED display panel with the clement Yb in the electron transport layer 14. In the fall range of visible wavelengths, 400 nm to 700 nm, the light transmittance of the disclosed OLED display panel D may be significantly higher than the light transmittance of the existing OLED display panel C, indicating that the introduction of the element Yb into the electron transport layer 14 may improve the light transmittance at the side where the second electrode 12 is disposed.

Furthermore, the organic luminescent layer 13 may include organic luminescent materials for realizing, white illumination. In one embodiment, the organic luminescent layer 13 may include a red light-emitting material a green light-emitting material and a blue light-emitting material. White light emission may be obtained by mixing the light emitted from the red, green and blue light-emitting materials.

FIG. 9 illustrates a schematic diagram of another exemplary OLED display panel consistent with disclosed embodiments. The similarities between FIG. 4 and FIG. 9 are not repeated here, while certain differences may be explained. As shown in FIG. 9, the OLED display panel 900 may further include a color filter layer or a color resist layer 15 disposed at the light output side of the OLED display panel 900, through which the white light emitted by the OLED display panel 900 may become colored light.

When the organic luminescent layer 13 may include a red light-emitting material, a green light-emitting material and a blue light-emitting material, the red light-emitting material, the green light-emitting material and the blue light-emitting material may vary according to various application scenarios. For example, in one embodiment, the red light-emitting materials and the green light-emitting materials may contain phosphorescent materials. The blue light-emitting materials may contain fluorescent materials, and the fluorescent materials may include thermally activated delayed fluorescent materials.

In addition, the red, the green, and the blue light-emitting materials may include host materials doped with guest materials. In one embodiment, the red light-emitting materials may comprise one host material or two host materials, the green light-emitting materials may comprise at least two host materials, and the blue-emitting materials may comprise one host material or two host materials.

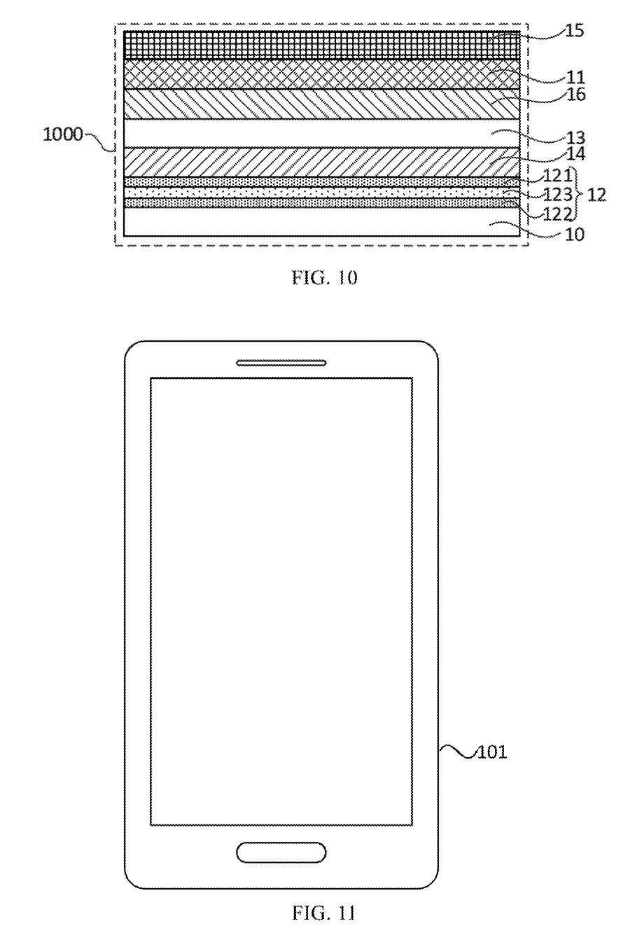

FIG. 10 illustrates a schematic diagram of another exemplary OLED display panel consistent with disclosed embodiments. The similarities between FIG. 9 and FIG. 10 are not repealed here, while certain differences may be explained. As shown in FIG. 10, the disclosed OLED display panel 1000 may further include a hole transport layer 16 disposed between the first electrode 11 and the organic luminescent layer 13.

The present disclosure also provides an OLED display apparatus. FIG. 11 illustrates a schematic diagram of an exemplary OLED display apparatus 101 consistent with the disclosed embodiments.

Referring to FIG. 11, the OLED display apparatus 101 may comprise any one of the disclosed OLED display panels and, thus, may also exhibit the same advantages as the disclosed OLED display panels. For example, the disclosed DEED display apparatus 101 may be a mobile phone, a notebook computer, a smart wearable device, and a public information inquiry machine, etc. Furthermore, the OLED display apparatus 101 may be any appropriate type of con tent-presentation devices including any of the disclosed OLED display panels.

Through introducing the element Yb with a volume percentage equal to or less than 3% into the electron transport layer 14, the disclosed OLED display panels and the OLED display apparatus may solve the problems of the substantially high interface barrier between the cathode and the electron transport layer 14 as well as the poor display performance. That is, the disclosed OLED display panels and OLED display apparatus may be able to reduce the substantially high interface barrier between the cathode and the electron transport layer 14, improve the electron injection capability and, accordingly, enhance the display performance.

The description of the disclosed embodiments is provided to illustrate the present invention to those skilled in the art. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. An organic light-emitting diode (OLED) display panel, comprising:
a substrate;
a first electrode and a second electrode, disposed in a stacked configuration and on a same side of the substrate;
an organic luminescent layer disposed between the first electrode and the second electrode; and
an electron transport layer, disposed between the organic luminescent layer and the second electrode and including a predetermined volume percentage of element ytterbium (Yb).

2. The OLED display panel according to claim 1, wherein:
the predetermined volume percentage of the element Yb is equal to of less than approximately 3%.

3. The OLED display panel according to claim 2, wherein:
the first electrode is disposed between the second electrode and the substrate.

4. The OLED display panel according to claim 3, wherein:
the OLED display panel is a top-emission OLED display panel;
the first electrode comprises a first transparent conductive film, a second transparent conductive film, and a reflective film sandwiched between the first transparent conductive film and the second reflective film; and
the second electrode comprises silver or a silver-based alloy.

5. The OLED display panel according to claim 3, wherein:
the OLED display panel is a bottom-emission OLED display panel;
the first electrode comprises a transparent and conductive material; and
the second electrode comprises silver or a silver-based alloy.

6. The OLED display panel according to claim 2, wherein:
the second electrode is disposed between the first electrode and the substrate;

7. The OLED display panel according to claim 6, wherein:
the OLED display panel is a top-emission OLED display panel;
the first electrode comprises a transparent and conductive material; and
the second electrode comprises silver or a silver-based alloy.

8. The OLED display panel according to claim 6, wherein:
the OLED display panel is a bottom-emission OLED display panel;
the first electrode comprises a first transparent conductive film, a second transparent conductive film, and a reflective film sandwiched between the first transparent conductive film and the second transparent conductive film; and
the second electrode comprises silver or a silver-based alloy.

9. The OLED display panel according to claim 4, wherein:
both the first transparent conductive film and the second transparent conductive film included in the first electrode comprise indium tin oxide or indium zinc oxide;
the reflective film comprises silver or a silver-based alloy;
a thickness of the reflective film ranges from approximately 50 nm to 150 nm.
the second electrode comprises the silver-based alloy having a volume percentage of silver equal to or larger than approximately 80%; and
a thickness of the second electrode ranges from approximately 10 nm to 20 nm.

10. The OLED display panel according to claim 8, wherein:
the first transparent conductive film and the second transparent conductive film included in the first electrode both comprise indium tin oxide or indium zinc oxide;
the reflective film comprises silver or a silver-based alloy;
a thickness of the reflective film ranges from approximately 50 nm to 150 nm.
the second electrode comprises the silver-based alloy having a volume percentage of silver equal to or larger than approximately 80%; and
a thickness of the second electrode ranges from approximately 10 nm to 20 nm.

11. The OLED display panel according to claim 5, wherein:
the transparent and conductive film comprises indium tin oxide or indium zinc oxide;
the second electrode comprises the silver-based alloy having a volume percentage of silver equal to or larger than approximately 80%; and
a thickness of the second electrode ranges from approximately 50 nm to 150 nm.

12. The OLED display panel according to claim 7, wherein:
the transparent and conductive film comprises indium tin oxide or indium zinc oxide;
the second electrode comprises the silver-based alloy having a volume percentage of silver equal to or larger than approximately 80%; and
a thickness of the second electrode ranges from approximately 50 nm to 150 nm.

13. The OLED display panel according to claim 2, wherein:
the organic luminescent layer contains a red light-emitting material, a green light-emitting material, and a blue light-emitting material.

14. The OLED display panel according to claim 13, wherein:
light emitted from the red light-emitting material, the green light-emitting material and the blue light-emitting material is mixed to obtain white light.

15. The OLED display panel according to claim 14, farther including:
a color filter layer or a color resist layer disposed at a light-output-side of the OLED display panel, wherein the obtained white light becomes colored light alter passing through the color filter layer or the color resist layer.

16. The OLED display panel according to claim 13, wherein:
the red light-emitting material and the green light-emitting material each comprises a phosphorescent material; and
the blue light-emitting material comprises a fluorescent material.

17. The OLED display panel according to claim 16, wherein:
the red light-emitting material, the green light-emitting material and the blue light-emitting material each includes a host material doped with a guest material;
the red light-emitting material comprises one host material or two host materials;
the green light-emitting material comprises at least two host materials; and
the blue light-emitting material comprises one host material or two host materials.

18. The OLED display panel according to claim 16, wherein:
the fluorescent material includes a thermally activated delayed fluorescent material.

19. The OLED display panel according to claim 2, farther including:
a hole transport layer disposed between the first electrode and the organic luminescent layer.

20. An OLED display apparatus comprising the OLED display panel according to claim 1.
